(19) United States
(12) Patent Application Publication
(10) Pub. No.: US 2015/0340228 A1
(43) Pub. Date: Nov. 26, 2015

(54) GERMANIUM-CONTAINING SEMICONDUCTOR DEVICE AND METHOD OF FORMING

(71) Applicants: Tokyo Electron Limited, Tokyo (JP); SEMATECH, Albany, NY (US)

(72) Inventors: Kandabara N. Tapily, Mechanicville, NY (US); David L. O'Meara, Albany, NY (US); Tat Ngai, Albany, NY (US)

(21) Appl. No.: 14/712,681

(22) Filed: May 14, 2015

Related U.S. Application Data
(60) Provisional application No. 61/993,146, filed on May 14, 2014.

(51) Int. Cl. H01L 21/02; H01L 29/167

(52) U.S. Cl. CPC H01L 21/02381; H01L 29/167; H01L 21/0245; H01L 21/02455

(57) ABSTRACT

A germanium-containing semiconductor device and a method for forming a germanium-containing semiconductor device are described. The method includes providing a germanium-containing substrate, depositing a silicon-containing interface layer on the germanium-containing substrate, depositing an aluminum-containing diffusion barrier layer on the silicon-containing interface layer, and depositing a high-k layer on the aluminum-containing diffusion barrier layer. The germanium-containing semiconductor device includes a germanium-containing substrate, a silicon-containing interface layer on the germanium-containing substrate, an aluminum-containing diffusion barrier layer on the silicon-containing interface layer, and a high-k layer on the aluminum-containing diffusion barrier layer.

### CROSS-REFERENCE TO RELATED APPLICATIONS

This application is related to and claims priority to U.S. provisional application Ser. No. 61/993,146 filed on May 14, 2014, the entire contents of which are herein incorporated by reference.

### FIELD OF THE INVENTION

The present invention generally relates to a semiconductor device, and more particularly to a germanium-containing semiconductor device with a high-mobility channel and method of forming.

### BACKGROUND OF THE INVENTION

As metal-oxide-semiconductor field-effect transistors (MOSFETs) continue to scale, a short channel effect has become an increasing problem and new device architectures such as FinFETs and trigates have been introduced. Semiconductor devices with a high-mobility channel, such as germanium (Ge)-containing semiconductor devices and III-V semiconductor devices, offer the possibility of increased device performance beyond traditional silicon (Si)-containing semiconductor devices. A challenge for germanium-containing semiconductor devices containing a high dielectric constant (high-k) film includes the need to protect the germanium-containing substrate against oxidation and/or degradation during deposition of the high-k film on the germanium-containing substrate.

### SUMMARY OF THE INVENTION

A germanium-containing semiconductor device and a method for forming a germanium-containing semiconductor device are described.

According to one embodiment, the method includes providing a germanium-containing substrate, depositing a silicon-containing interface layer on the germanium-containing substrate, depositing an aluminum-containing diffusion barrier layer on the silicon-containing interface layer, and depositing a high-k layer on the aluminum-containing diffusion barrier layer. In one embodiment, the silicon-containing interface layer includes a SiO₂ layer and the aluminum-containing diffusion barrier layer includes an Al₂O₃ layer.

According to another embodiment, a germanium-containing semiconductor device is described. The device includes a germanium-containing substrate, a silicon-containing interface layer on the germanium-containing substrate, an aluminum-containing diffusion barrier layer on the silicon-containing interface layer, and a high-k layer on the aluminum-containing diffusion barrier layer.

### BRIEF DESCRIPTION OF THE DRAWINGS

In the accompanying drawings:

FIGS. 1A-1F schematically show cross-sectional views of a method of forming a germanium-containing semiconductor device according to an embodiment of the invention;

FIG. 2 shows a process flow diagram for a method of forming a germanium-containing semiconductor device according to an embodiment of the invention; and

FIGS. 3A-3B, 4A-4B, 5A-5B and 6 show measured transconductance (Gₘ×L/W) and drive current (I_{d}) as a function of gate voltage (Vg) for different germanium-containing test samples.

### DETAILED DESCRIPTION OF SEVERAL EMBODIMENTS

A challenge for advanced germanium-containing semiconductor devices includes the need to protect a germanium-containing substrate against oxidation and/or degradation during semiconductor processing, for example during deposition of a high-k film on the Germanium-containing substrate. Embodiments of the invention describe a method for forming a bilayer that acts as a passivation film between the germanium-containing substrate and the high-k film. The passivation film contains a silicon-containing interface layer on the germanium-containing substrate and an aluminum-containing diffusion barrier layer on the silicon-containing interface layer. According to embodiments of the invention, the silicon-containing interface layer (e.g., SiO₂) provides an interface with good electrical characteristics with the germanium-containing substrate and the aluminum-containing diffusion barrier layer (e.g., Al₂O₃) provides a good barrier to germanium diffusion into overlying films and layers (e.g., a high-k layer), and good barrier to oxygen diffusion into the germanium-containing substrate. The bilayer has been shown to result improved transconductance and drive current characteristics for germanium-containing semiconductor devices.

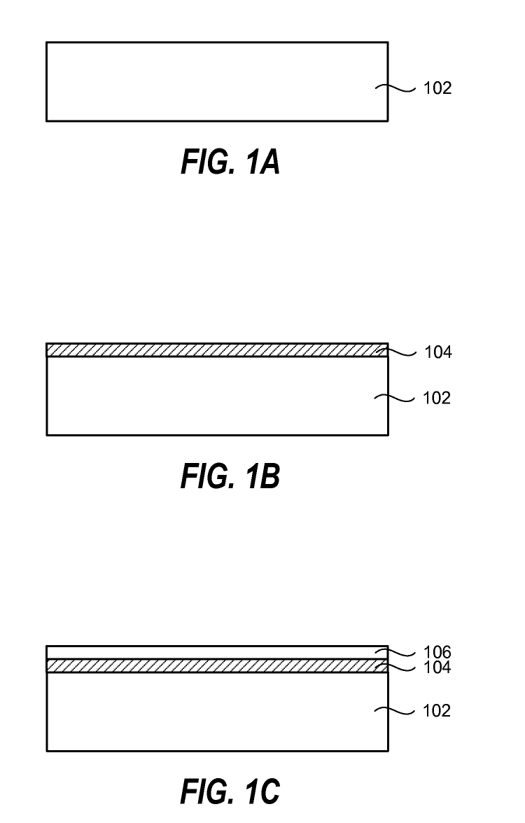

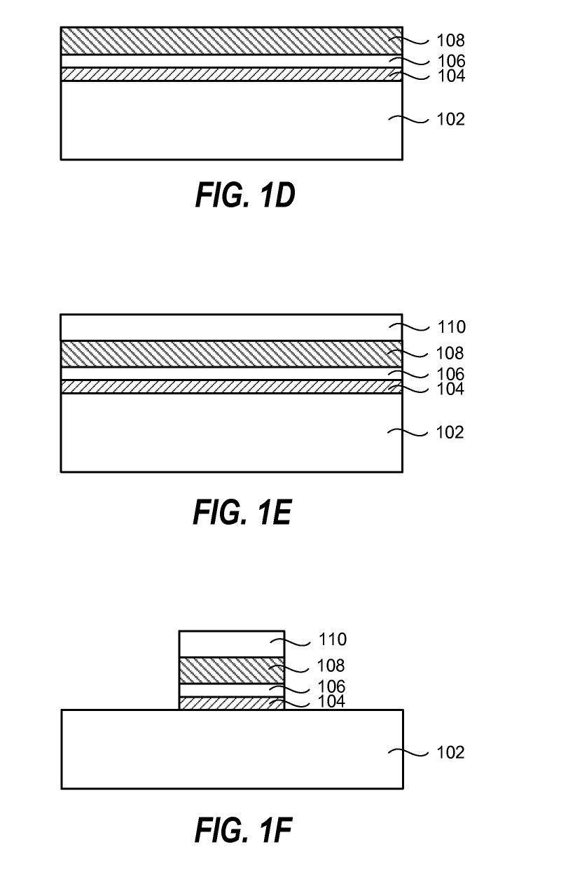

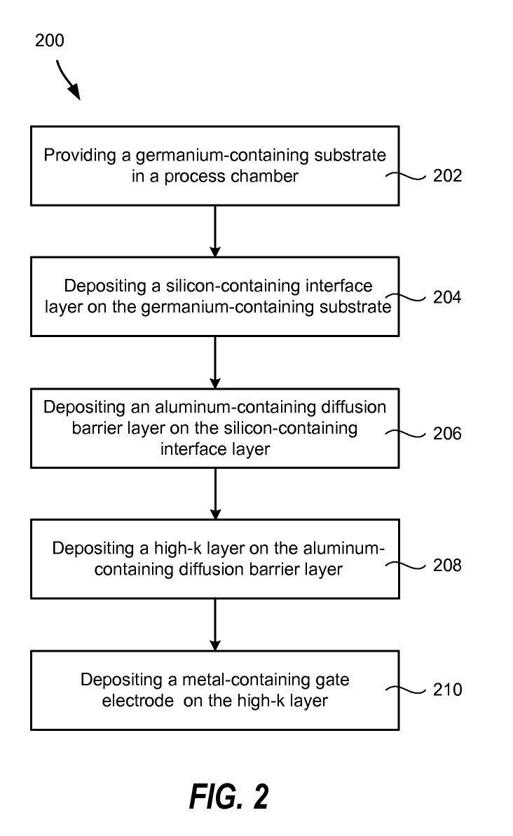

Referring now to the figures, FIGS. 1A-1F schematically show cross-sectional views of a method of forming a germanium-containing semiconductor device according to an embodiment of the invention, and FIG. 2 shows a process flow diagram 200 for a method of forming a germanium-containing semiconductor device according to an embodiment of the invention. In 202, a germanium-containing substrate 102 is provided in a process chamber. In some examples, the process chamber may be capable of performing thin film deposition that can selected from atomic layer deposition (ALD), chemical vapor deposition (CVD), plasma-enhanced ALD (PEALD), and plasma-enhanced CVD (PECVD). The germanium-containing substrate 102 can include Ge or SiGe. The SiGe can be expressed as SiₓGe₁₋ₓ, where x is the atomic fraction of Si and 1−x is the atomic fraction of Ge. Exemplary SiₓGe₁₋ₓ compounds include Si_{0.1}Ge_{0.9}, Si_{0.2}Ge_{0.8}, Si_{0.3}Ge_{0.7}, Si_{0.4}Ge_{0.6}, Si_{0.5}Ge_{0.5}, Si_{0.6}Ge_{0.4}, Si_{0.7}Ge_{0.3}, Si_{0.8}Ge_{0.2}, and Si_{0.9}Ge_{0.1}. The germanium-containing substrate 102 may be cleaned of any oxide layer or contaminants using dilute hydrofluoric acid (DHF) or a chemical oxide removal process (COR). Thus, a surface of the germanium-containing substrate 102 may be prepared to be substantially free of oxygen. Alternatively, a GeO₂ layer (not shown) may be formed on the germanium-containing substrate 102. However, the presence of a GeO₂ layer can increase the equivalent oxide thickness (EOT) of the final germanium-containing semiconductor device.

In 204, a silicon-containing interface layer 104 is deposited on the germanium-containing substrate 102 (FIG. 1B). A thickness of the silicon-containing interface layer 104 can be, for example, between about 3 angstrom (Å) and about 20 Å, between about 3 Å and about 10 Å, or between about 4 Å and about 6 Å. In one embodiment, the silicon-containing interface layer 104 can contain SiO₂, SiON, SiN, or a combination thereof. In one embodiment, the silicon-containing interface layer 104 may be deposited on a GeO₂ layer (not shown) on the germanium-containing substrate 102. The silicon-containing interface layer 104 may be deposited onto the germanium-containing substrate 102 by ALD, CVD, PEALD, or PECVD, using a silicon precursor, and an oxidation source, a nitridation source, or both an oxidation source and a nitridation source.

Embodiments of the invention may utilize a wide variety of silicon precursors for depositing the silicon-containing interface layer 104. Examples of silicon precursors include, but are not limited to, silane (SiH₄), disilane (Si₂H₆), monochlorosilane (SiClH₃), dichlorosilane (SiH₂Cl₂), trichlorosilane (SiHCl₃), hexachlorodisilane (Si₂Cl₆), diethylsilane (Et₂SiH₂), tetra-ethyl orthosilicate (TEOS, Si(OCH₂CH₃)₄), and alkylaminosilane compounds. Examples of alkylaminosilane compounds include, but are not limited to, di-isopropylaminosilane (H₃Si(NPr₂)), bis(tert-butylamino)silane ((C₄H₉(H)N)₂SiH₂), tetrakis(dimethylamino)silane (Si(NMe₂)₄), tetrakis(ethylmethylamino)silane (Si(NEtMe)₄), tetrakis(diethylamino)silane (Si(NEt₂)₄), tris(dimethylamino)silane (HSi(NMe₂)₃), tris(ethylmethylamino)silane (HSi(NEtMe)₃), tris(diethylamino)silane (HSi(NEt₂)₃), and tris(dimethylhydrazino)silane (HSi(N(H)NMe₂)₃), bis(diethylamino)silane (H₂Si(NEt₂)₂), bis(di-isopropylamino)silane (H₂Si(NPr₂)₂), tris(isopropylamino)silane (HSi(NPr₂)₃), and (di-isopropylamino)silane (H₃Si(NPr₂).

Embodiments of the invention may utilize a wide variety of oxidation sources and nitridation sources for depositing the silicon-containing interface layer 104. The oxidation sources can include, but are not limited to, O₂, atomic oxygen (O), ozone (O₃), water (H₂O), or peroxide (H₂O₂), or a combination thereof, and optionally an inert gas such as Ar. The nitridation sources can include, but are not limited to, ammonia (NH₃), atomic nitrogen (N), hydrazine (N₂H₄), and C₁-C₁₀ alkylhydrazine compounds. Common C₁ and C₂ alkylhydrazine compounds include monomethyl-hydrazine (MeNHNH₂), 1,1-dimethyl-hydrazine (Me₂NNH₂), and 1,2-dimethyl-hydrazine (MeNHNHMe). According to one embodiment, a mixture of the oxidation sources and the nitridation sources may be utilized. According to one embodiment, an oxidation and nitridation source may, for example, contain NO, NO₂, or N₂O, or a combination thereof, and optionally an inert gas such as Ar.

In 206, an aluminum-containing diffusion barrier layer 106 is deposited on the silicon-containing interface layer 104 (FIG. 1C). A thickness of the aluminum-containing diffusion barrier layer 106 can be, for example, between about 3 Å and about 20 Å, between about 3 Å and about 10 Å, or between about 4 Å and about 6 Å. In one embodiment, the aluminum-containing diffusion barrier layer 106 can contain aluminum oxide (Al₂O₃), aluminum oxynitride (AlON), aluminum nitride (AlN), or a combination thereof. The aluminum-containing diffusion barrier layer 106 may be deposited onto the silicon-containing interface layer 104 by ALD, CVD, PEALD, or PECVD, using an aluminum precursor, and an oxidation source, a nitridation source, or both an oxidation source and a nitridation source.

Embodiments of the invention may utilize a wide variety of aluminum precursors for depositing the aluminum-containing diffusion barrier layer 106. Examples of aluminum precursors include, but are not limited to, AlMe₃, AlEt₃, AlMe₂H, [Al(OsBu)₃]₄, Al(CH₃COCHCOCH₃)₃, AlCl₃, AlBr₃, AlI₃, Al(OiPr)₃, [Al(NMe₂)₃]₂, Al(iBu)₂Cl, Al(iBu)₃, Al(iBu)₂H, AlEt₂Cl, Et₃Al₂(OsBu)₃, Al(THD)₃, H₃AlNMe₃, H₃AlNEt₃, H₃AlNMe₂Et, and H₃AlMeEt₂.

Embodiments of the invention may utilize a wide variety of oxidation sources and nitridation sources for depositing the aluminum-containing diffusion barrier layer 106. The oxidation sources can include, but is not limited to, O₂, atomic oxygen (O), ozone (O₃), water (H₂O), or peroxide (H₂O₂), or a combination thereof, and optionally an inert gas such as Ar. The nitridation sources can include, but is not limited to, ammonia (NH₃), atomic nitrogen (N), hydrazine (N₂H₄), and C₁-C₁₀ alkylhydrazine compounds. Common C₁ and C₂ alkylhydrazine compounds include monomethyl-hydrazine (MeNHNH₂), 1,1-dimethyl-hydrazine (Me₂NNH₂), and 1,2-dimethyl-hydrazine (MeNHNHMe). According to one embodiment, a mixture of the oxidation sources and the nitridation sources may be utilized. According to one embodiment, an oxidation and nitridation source may, for example, contain NO, NO₂, or N₂O, or a combination thereof, and optionally an inert gas such as Ar.

In 208, a high-k layer 108 is deposited on the aluminum-containing diffusion barrier layer 106 (FIG. 1D). A thickness of the high-k layer 108 can be, for example, between about 1 nm and about 10 nm, between about 1.5 nm and about 5 nm, or between about 2 nm and about 4 nm. The high-k layer 108 may be deposited onto the aluminum-containing diffusion barrier layer 106 by ALD, CVD, PEALD, or PECVD, using a high-precursor, and an oxidation source, a nitridation source, or both an oxidation source and a nitridation source.

In one embodiment, the high-k layer 108 includes hafnium, zirconium, titanium, a rare earth element, or a combination thereof. Examples include TiO₂, HfO₂, ZrO₂, HfSiO, ZrSiO, HfON, ZrON, HfZrO, HfZrON), HfZrSiO, or HfZrSiON, or a combination of two or more thereof. In other examples, the high-k layer 108 can include an oxide, nitride, or oxynitride containing a rare earth element, such as yttrium (Y), lutetium (Lu), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), or ytterbium (Yb), or any combination of two or more thereof. Examples of a rare earth-based high-k layer 108 include lanthanum oxide (La₂O₃), lutetium oxide (Lu₂O₃), and lanthanum lutetium oxide (LaLuO₃).

Embodiments of the invention may utilize a wide variety of oxidation sources and nitridation sources for depositing the high-k layer 108. The oxidation sources can include, but is not limited to, O₂, atomic oxygen (O), ozone (O₃), water (H₂O), or peroxide (H₂O₂), or a combination thereof, and optionally an inert gas such as Ar. The nitridation sources can include, but is not limited to, ammonia (NH₃), atomic nitrogen (N), hydrazine (N₂H₄), and C₁-C₁₀ alkylhydrazine compounds. Common C₁ and C₂ alkylhydrazine compounds include monomethyl-hydrazine (MeNHNH₂), 1,1-dimethyl-hydrazine (Me₂NNH₂), and 1,2-dimethyl-hydrazine (MeNHNHMe). According to one embodiment, a mixture of the oxidation sources and the nitridation sources may be utilized. According to one embodiment, an oxidation and nitridation source may, for example, contain NO, NO₂, or N₂O, or a combination thereof, and optionally an inert gas such as Ar.

In 210, a metal-containing gate electrode 110 is deposited on the high-k layer 108 (FIG. 1E). In one embodiment, the metal-containing gate electrode 110 can include TiN, TiAlN, W, or TaN, or a combination of two or more thereof. Following deposition of the metal-containing gate electrode 110, the film structure may be further processed to form a gate stack as schematically shown in FIG. 1F.

In one embodiment, one or more of the silicon-containing interface layer 104, aluminum-containing diffusion barrier layer 106, high-k layer 108, and metal-containing gate electrode 110, may be deposited by ALD. In one example, one or more of the ALD processes may be carried out at substrate temperatures below 300° C.

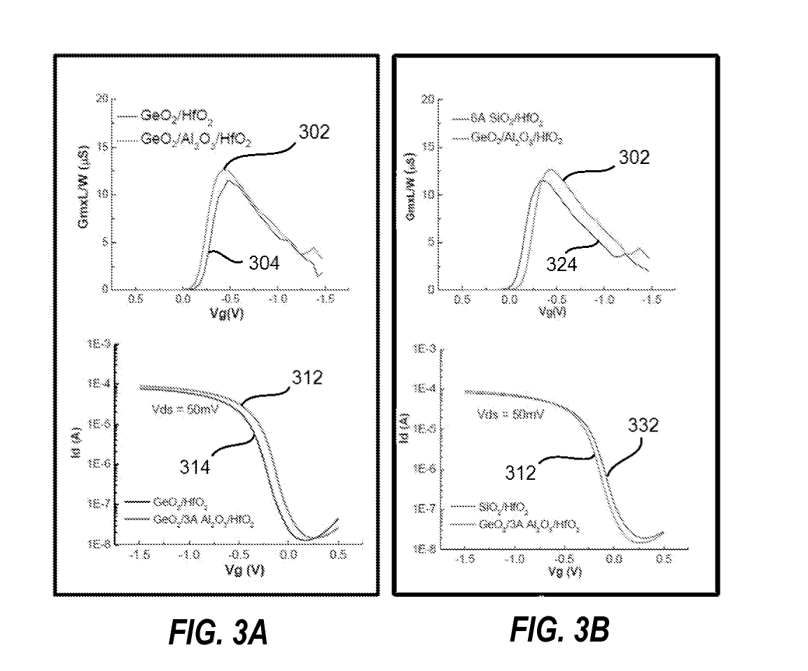

FIGS. 3A-3B, 4A-4B, 5A-5B and 6 show measured transconductance (Gₘ×L/W) and drive current (I_{d}) as a function of gate voltage (Vg) for different germanium-containing test samples. Transconductance is a measure of electric mobility in semiconductor devices.

FIG. 3A-3B show measured transconductance and drive current as a function of gate voltage (V_{g}) for GeO₂/HfO₂ (304, 314), GeO₂/Al₂O₃/HfO₂ (302,312), and Ge/SiO₂/HfO₂ (324, 332) test samples. The test samples included Ge substrates and further included a metal-containing gate electrode on the HfO₂ high-k layer. The Al₂O₃ layer was 3 Å thick, the SiO₂ layer was 6 Å thick, and the HfO₂ layer was 3 nm thick. The Al₂O₃, SiO₂, and HfO₂ layers were deposited by ALD. The measured gate oxide thickness in the inversion mode (tᵢₙᵥ) was 11 Å for the GeO₂/HfO₂ test sample, 13.7 Å for the GeO₂/Al₂O₃/HfO₂ test sample, and 12.7 Å for the Ge/SiO₂/HfO₂ test sample. The transconductance and the drive current were improved after passivating the GeO₂ layer with Al₂O₃ or SiO₂ layers. Further, the Al₂O₃ layer improved the electrical properties of the test samples more than the SiO₂ layer.

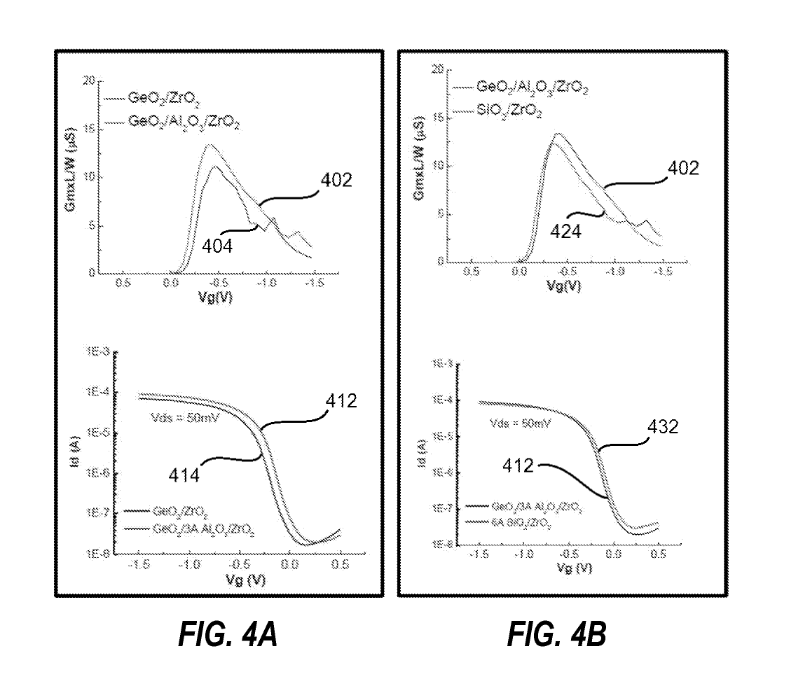

FIGS. 4A-4B show measured transconductance and drive current as a function of gate voltage (V_{g}) for GeO₂/ZrO₂ (404, 414), GeO₂/Al₂O₃/ZrO₂ (402, 412), and Ge/SiO₂/ZrO₂ (424, 432) test samples. The test samples included Ge substrates and further included a metal-containing gate electrode on the ZrO₂ layer. The Al₂O₃ layer was 3 Å thick, the SiO₂ layer was 6 Å thick, and the ZrO₂ layer was 3 nm thick. The Al₂O₃, SiO₂, and ZrO₂ layers were deposited by ALD. The tᵢₙᵥ was 10.2 Å for the GeO₂/ZrO₂ test sample, 12.4 Å for the GeO₂/Al₂O₃/ZrO₂ test sample, and 10.8 Å for the Ge/SiO₂/ZrO₂ test sample. Similar to the HfO₂-containing test samples in FIGS. 3A-3B, the transconductance and the drive current for the ZrO₂-containing structures in FIGS. 4A-4B were improved after passivating the GeO₂ layer with Al₂O₃ or SiO₂ layers. Further, the Al₂O₃ layer improved the electrical properties of the test samples more than the SiO₂ layer.

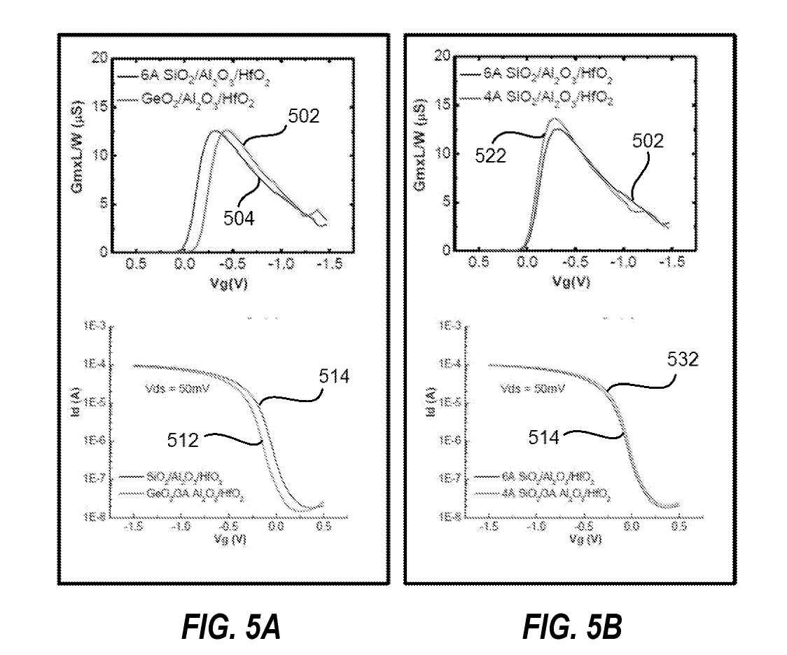

FIGS. 5A-5B show measured transconductance and drive current as a function of gate voltage (V_{g}) for Ge/SiO₂ (6 Å)/Al₂O₃/HfO₂ (504, 514), Ge/SiO₂ (4 Å)/Al₂O₃/HfO₂ (522, 532), GeO₂/Al₂O₃/HfO₂ (502, 512) test samples. The test samples included Ge substrates and the test samples further included a metal-containing gate electrode on the HfO₂ layer. The Al₂O₃ layer was 3 Å thick, the SiO₂ layer was 6 Å thick or 4 Å thick, and the HfO₂ layer was 3 nm thick. The Al₂O₃, SiO₂, and HfO₂ layers were deposited by ALD. The tᵢₙᵥ was 13.3 Å for the Ge/SiO₂ (4 Å)/Al₂O₃/HfO₂ test sample, and 13.7 Å for the GeO₂/Al₂O₃/HfO₂ test sample. The SiO₂/Al₂O₃ bilayer test samples showed reduced hysteresis, improved drive current, while preserving the transconductance and the mobility compared to a single SiO₂ or Al₂O₃ layer.

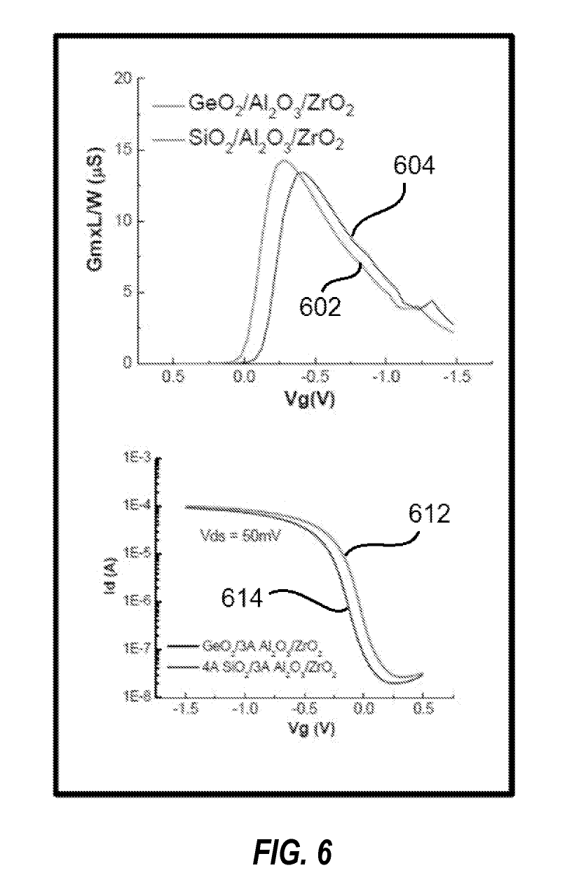

FIG. 6 shows measured transconductance and drive current as a function of gate voltage (V_{g}) for Ge/SiO₂/Al₂O₃/ZrO₂ (602, 612) and GeO₂/Al₂O₃/ZrO₂ (604, 614) test samples. The test samples included Ge substrates and further included a metal-containing gate electrode on the ZrO₂ layer. The Al₂O₃ layer was 3 Å thick, the SiO₂ layer was 4 Å thick, and the ZrO₂ layer was 3 nm thick. The Al₂O₃, SiO₂, and ZrO₂ layers were deposited by ALD. The tᵢₙᵥ was 11.6 Å for the Ge/SiO₂/Al₂O₃/ZrO₂ test sample, and 12.4 Å for the GeO₂/Al₂O₃/ZrO₂ test sample. The SiO₂/Al₂O₃ bilayer test samples showed reduced hysteresis, improved drive current, while preserving the transconductance and the mobility compared to a single SiO₂ or Al₂O₃ layer.

The results in FIGS. 3A-3B, 4A-4B, 5A-5B and 6 show that SiO₂/Al₂O₃ bilayer structures on Ge substrates have improved electrical properties over structures containing a single SiO₂ or Al₂O₃ layer. The SiO₂ interface layer provides a good interface with Ge substrate and the Al₂O₃ diffusion barrier layer provides a good diffusion barrier to Ge diffusion into the high-k layer, and good barrier to oxygen diffusion into the germanium-containing substrate.

A germanium-containing semiconductor device and a method of forming have been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method for forming a germanium-containing semiconductor device, the method comprising:
providing a germanium-containing substrate:
depositing a silicon-containing interface layer on the germanium-containing substrate;
depositing an aluminum-containing diffusion barrier layer on the silicon-containing interface layer; and
depositing a high-k layer on the aluminum-containing diffusion barrier layer.

2. The method of claim 1, wherein the germanium-containing substrate includes Ge or SiGe.

3. The method of claim 1, wherein the germanium-containing substrate further contains a GeO₂ layer thereon and the silicon-containing interface layer is deposited on the GeO₂ layer.

4. The method of claim 1, wherein a surface of the germanium-containing substrate is substantially free of oxygen.

5. The method of claim 1, wherein the silicon-containing interface layer contains SiO₂, SiON, SiN, or a combination thereof.

6. The method of claim 1, wherein the aluminum-containing diffusion barrier layer contains aluminum oxide, aluminum oxynitride, aluminum nitride, or a combination thereof.

7. The method of claim 1, wherein the high-k layer contains hafnium, zirconium, titanium, a rare earth element, or a combination thereof.

8. A method for forming a germanium-containing semiconductor device, the method comprising:
providing a germanium-containing substrate:
depositing a SiO₂ interface layer on the germanium-containing substrate;
depositing an Al₂O₃ diffusion barrier layer on the SiO₂ interface layer; and
depositing a high-k layer on the Al₂O₃ diffusion barrier layer.

9. The method of claim 8, wherein the germanium-containing substrate includes Ge or SiGe.

10. The method of claim 8, wherein the germanium-containing substrate further contains a GeO₂ layer thereon and the silicon-containing interface layer is deposited on the GeO₂ layer.

11. The method of claim 8, wherein a surface of the germanium-containing substrate is substantially free of oxygen.

12. The method of claim 8, wherein the silicon-containing interface layer contains SiO₂, SiON, SiN, or a combination thereof.

13. The method of claim 8, wherein the high-k layer contains hafnium, zirconium, titanium, a rare earth element, or a combination thereof.

14. A germanium-containing semiconductor device, comprising:
a germanium-containing substrate:
a silicon-containing interface layer on the germanium-containing substrate;
an aluminum-containing diffusion barrier layer on the silicon-containing interface layer; and
a high-k layer on the aluminum-containing diffusion barrier layer.

15. The device of claim 14, wherein the germanium-containing substrate includes Ge or SiGe.

16. The device of claim 14, wherein the germanium-containing substrate further contains a GeO₂ layer thereon and the silicon-containing interface layer is deposited on the GeO₂ layer.

17. The device of claim 14, wherein a surface of the germanium-containing substrate is substantially free of oxygen.

18. The device of claim 14, wherein the silicon-containing interface layer contains SiO₂, SiON, SiN, or a combination thereof.

19. The device of claim 14, wherein the aluminum-containing diffusion barrier layer contains aluminum oxide, aluminum oxynitride, aluminum nitride, or a combination thereof.

20. The device of claim 14, wherein the high-k layer contains hafnium, zirconium, titanium, a rare earth element, or a combination thereof.
